(19) United States
(12) Patent Application Publication
(10) Pub. No.: US 2011/0292624 A1
(43) Pub. Date: Dec. 1, 2011

(54) ELECTRONIC CONTROL UNIT

(75) Inventors: Takaaki TANAKA, Chiyoda-ku (JP); Yasuhiro TAKAHASHI, Chiyoda-ku (JP); Toru KUBO, Minato-ku (JP); Seiji KATO, Minato-ku (JP); Masako MITANI, Chiyoda-ku (JP); Hideki UMEMOTO, Chiyoda-ku (JP)

(73) Assignee: MITSUBISHI ELECTRIC CORPORATION, Tokyo (JP)

(21) Appl. No.: 12/901,215

(22) Filed: Oct. 8, 2010

(30) Foreign Application Priority Data
May 26, 2010 (JP) 2010-120537

(51) Int. Cl. H05K 5/00

(52) U.S. Cl. 361/752

(57) ABSTRACT

An electronic control unit includes an electronic circuit board mounted with a plurality of electronic components disposed in a scattered manner on one or both surfaces of the board and at least one connector, and the electronic circuit board is housed in an enclosure made up of enclosure members including a cover and a base, wherein the electronic control unit is structured in such a way that intermediate members each are disposed on both top face of a part of or all of the electronic components and their projected area on the opposite mount surface of the board, portions of the enclosure members are made to closely contact the intermediate members so that both surfaces of the electronic circuit board are sandwiched by the enclosure members and the intermediate members, and edge portions in the periphery of the electronic circuit board are sandwiched by the enclosure members.

### FIELD OF THE INVENTION

The present invention relates to an electronic control unit in which electronic components are mounted on an electronic circuit board (printed circuit board) and the board is housed in an enclosure.

### DESCRIPTION OF THE RELATED ART

An electronic control unit (hereinafter referred to also as an ECU; used for controlling a motor vehicle and the like is generally structured in such a way that components constituting electronic circuits, such as an input/output circuit, a communication circuit, a micro processor and a power supply circuit, are disposed on an electronic circuit board and housed in an enclosure.

Those electronic components constituting the ECU generate heat depending on their circuit operations. A large current can flow through such electronic circuits, which may sometimes lead to breakdown of the circuits and components thereof, unless appropriate countermeasures are taken for dissipating heat.

Therefore, various countermeasures for the heat dissipation have been put into practice. In particular, as a method of dissipating heat from high-heat-generating electronic components, a structure has been introduced in which the top face of the electronic components or their projected area on the opposite mount surface of the board is made to contact a metal enclosure via a thermal conductor and the like so as to dissipate heat, as described in Japanese Patent No. 440759 and Japanese Laid-open Patent No. 2003-289191 (hereinafter referred to as Patent Document 1 and 2, respectively).

As described above, the method of making the electronic components on the hoard contact an enclosure member sc as to dissipate heat is particularly effective for dissipating high heat generated by the electronic components. However, when heat is dissipated by introducing such a structure as described above, the unit is assembled using screws so as to secure close contact between a thermally conductive thin film layer and the metal enclosure, which has therefore caused problems of the number of components increasing and the production process becoming complicated.

### SUMMARY OF THE INVENTION

The present invention has been made to solve problems with the conventional electronic control unit described above, and aims at providing an electronic control unit in which manufacturing costs can be reduced by simplifying the production process, heat dissipation capability can be enhanced, and as a result, reduction in the size and weight of the unit can be realized.

An electronic control unit according to the present invention includes an electronic circuit board mounted with a plurality of electronic components disposed in a scattered manner on one or both surfaces of the board and at least one connector, and the electronic circuit board is structurally housed in an enclosure made up of enclosure members including a cover and a base, wherein the electronic control unit is structured in such a way that intermediate members each are disposed on both top face of a part of or all of the electronic components and their projected area on the opposite mount surface of the board, portions of the enclosure members are made to closely contact the intermediate members so that both surfaces of the electronic circuit board are sandwiched by the enclosure members and the intermediate members, and edge portions in the periphery of the electronic circuit board are sandwiched by the enclosure members.

In an electronic control unit according to the present invention, its assembly process can be simplified because no screws are used in assembling the enclosure, the manufacturing costs can be reduced thanks to reduction in process, and heat dissipation capability per unit board area can be enhanced, so that an electronic control unit can be provided in which reduction in the size and weight thereof can be realized.

The foregoing and other object, features, aspects and advantages of the present invention will become more apparent from the following detailed description of the present invention when taken in conjunction with the accompanying drawings.

### BRIEF DESCRIPTION OF THE DRAWINGS

FIG. 1 is an external view of an electronic control unit according to Embodiment 1 of the present invention;

FIG. 2 is an exploded perspective view schematically showing the internal structure of the electronic control unit according to Embodiment 1 of the invention;

FIG. 3 is an essential-portion cross sectional view of the electronic control unit according to Embodiment 1 of the invention;

FIG. 4 is an essential-portion cross sectional view exemplifying the shape of a cover and a state of the cover closely contacting electronic components in the electronic control unit according to Embodiment 1 of the invention;

FIG. 5 is a view exemplifying disposal of electronic components in a scattered manner on a board of the electronic control unit according to Embodiment 1 of the invention;

FIG. 6 is a view exemplifying a method of connecting the cover with a base of the electronic control unit according to Embodiment 1 of the invention; and

FIG. 7 is an explanatory view exemplifying a method of connecting a connector holding member of a connector section with the cover and the base.

### DETAILED DESCRIPTION OF THE PREFERRED EMBODIMENTS

### Embodiment 1

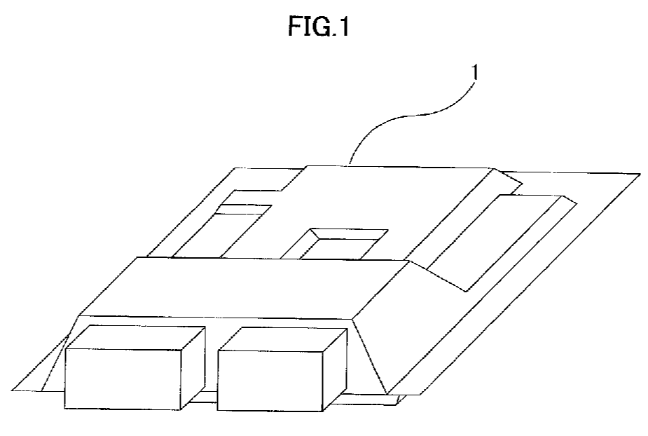

Hereinafter, an electronic control unit according to Embodiment 1 of the present invention will be explained in detail referring to FIG. 1 to FIG. 7. In each drawing, the same reference numeral denotes the same or corresponding part.

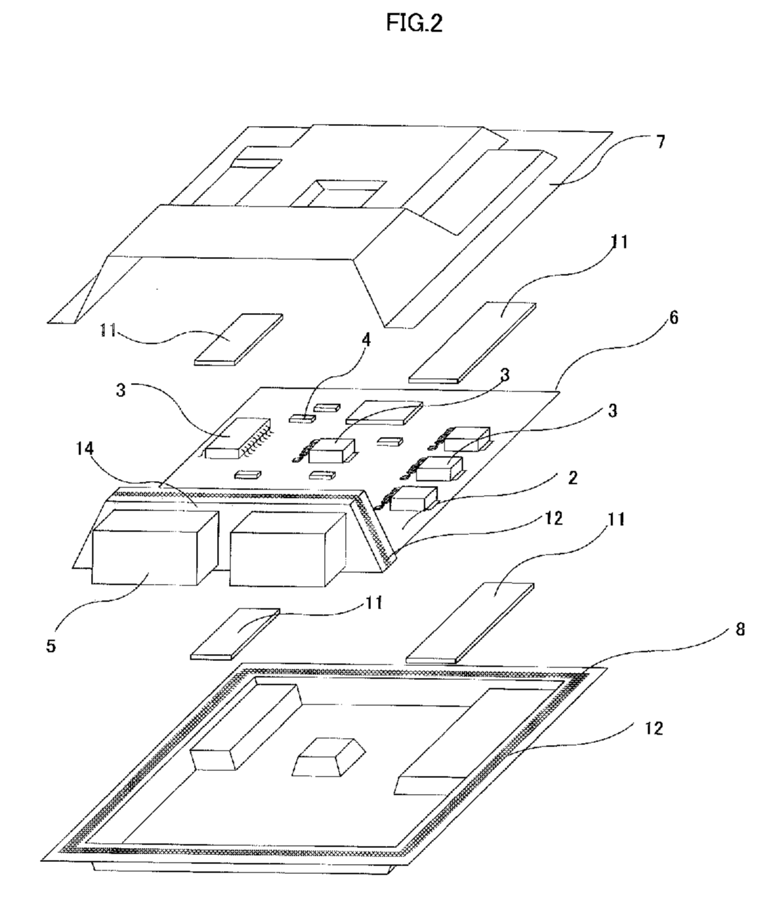

FIG. 1 is a perspective view showing the external appearance of the electronic control unit (hereinafter referred to also as an ECU) 1; FIG. 2 is an exploded perspective view schematically showing the internal structure of the electronic control unit. As shown in FIG. 2, in the ECU 1, a plurality of heat-generating electronic components (hereinafter referred to also as heat-generating components) 3 and other electronic components 4 are mounted on an electronic circuit board (hereinafter simply referred to as a board) 2. Furthermore, in order to connect the ECU 1 with other input/output units (not shown in the figure), a connector 5 provided with a connector holding member 14, which is integrated together with the connector or a separate piece, is mounted on the board, thereby constituting a circuit assembly 6.

In this Embodiment 1, all of the heat-generating components 3 and the connector 5 are assumedly mounted on the same planar surface of the board 2, and the other components 4 are assumedly mounted on both surfaces of the board 2. Here, the surface on which the heat-generating components 3, the connector 5 and part of the other components 4 are mounted is defined as a mount surface, whereas the other surface on which only remaining part of the other components 4 are mounted is defined as an opposite mount surface. It goes without saying that even when the heat generating components 3 are actually mounted on the opposite mount surface defined in this Embodiment 1, the same idea can be easily implemented.

The mount surface and the opposite mount surface of the circuit assembly 6 are covered with the cover 7 and the base 8, respectively, which constitute the enclosure. Contact surfaces of the cover 7 and the base 8 each are contacted with the interface of the connector holding member 14. Taking heat dissipation capability into consideration, the cover 7 and the base 8 are preferably made of a material such as metal that has a high thermal conductivity. However, when they are used for the purpose of mainly holding the board and don't need heat dissipation capability, materials other than metal can be utilized without causing any problem.

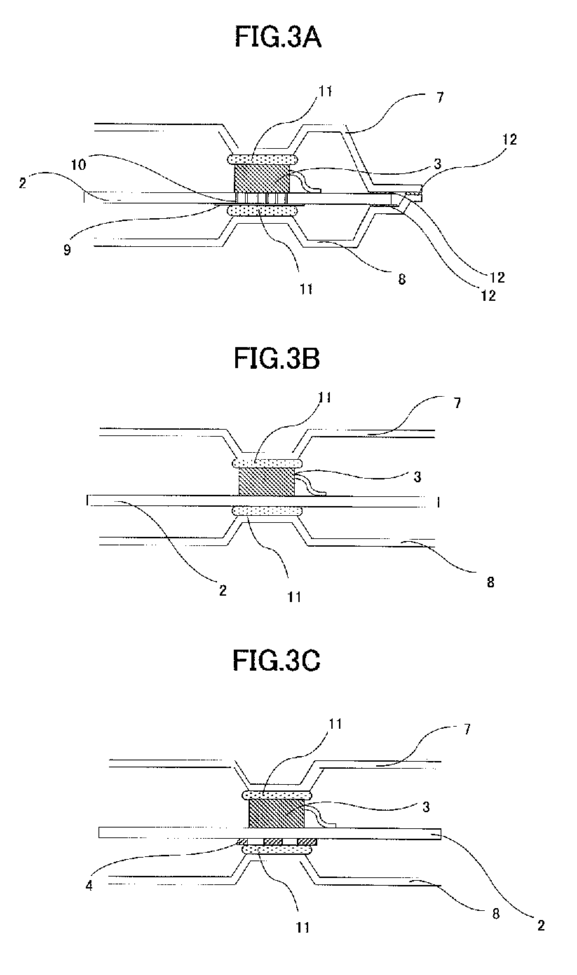

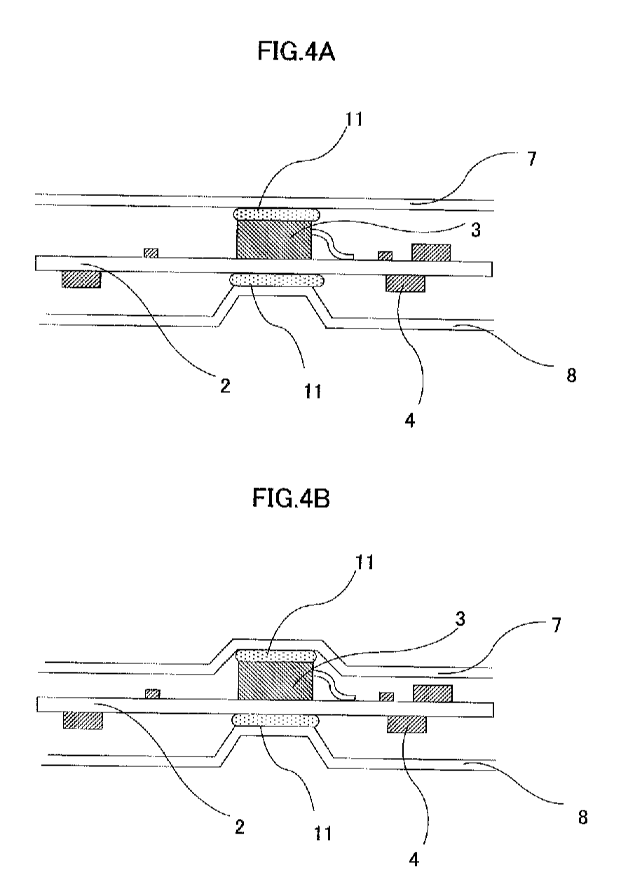

FIG. 3 and FIG. 4 show part of the cross sectional structure of the ECU 1. Hereinafter, how to hold the board 2 will be explained in detail.

In FIG. 3, the heat-generating components 3 are mounted on the mount surface of the board 2. Moreover, when heat dissipation capability is of utmost importance, it is preferable to structure the circuit assembly 6 in such a way that a thermally conductive thin film layer 9, which is a so-called heat-dissipating pattern including a copper layer as shown in FIG. 3A, is provided in the projected area of the heat-generating components 3, on the opposite mount surface, and the mount surface and the opposite mount surface are connected with each other by through-holes 10 and the like, so that heat generated by the heat-generating components 3 is led to the opposite mount surface. Meanwhile, when the heat dissipation capability is not so important, the through-holes 10 and the thermally conductive thin film layer 9 don't need to be provided as shown in FIG. 3B. Moreover, when reduction in the size of the ECU is of utmost importance, a structure as shown in FIG. 3C is conceivable in which the other components 4 are mounted on the opposite mount surface.

Thermal conductors 11 having high insulation and flexibility are disposed on the top face of the heat-generating components 3 and their projected area on the opposite mount surface, and furthermore, the cover 7 and the base 8 whose portions corresponding to the projected area of the heat-generating components 3 are protruded inward of the ECU 1 are arranged no that the board 2 is sandwiched between the cover and the base. The thermal conductors 11 play a role of effectively leading heat generated by the heat-generating components 3 to the enclosure made up of the cover 7 and the base 8 as well as a role of making the enclosure and the circuit assembly 6 closely contact each other, being interposed therebetween, so as to hold the circuit assembly 6, and in turn, the board 2 in the enclosure.

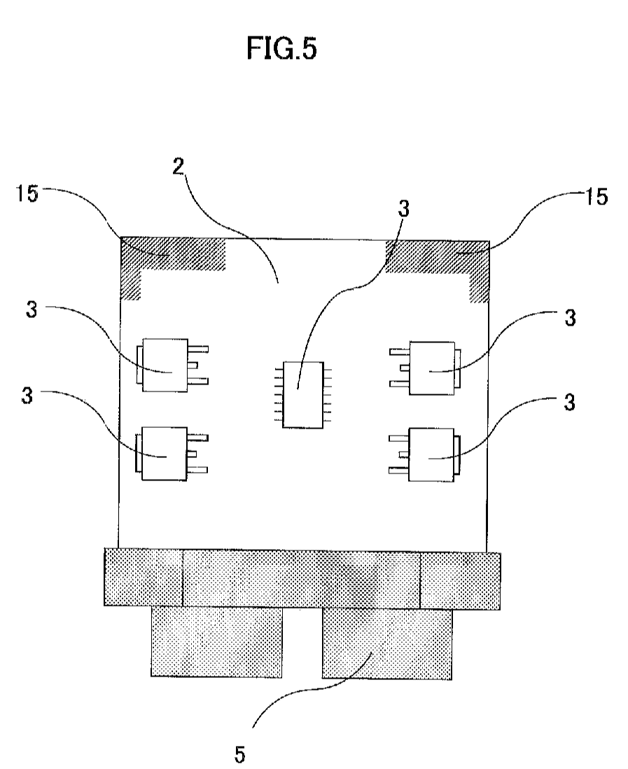

Moreover, as shown in FIG. 3A, the board 2 is sandwiched also at the periphery thereof, by the cover 7 and the base 8, directly or via intermediate members such as glue 12 and the thermal conductors, whereby the board is held at additional points. Here, it is conceivable that those holding points in the periphery of the board are provided in a part of or the whole of the board periphery as shown by hatching portions 15 on the board 2 in the view of FIG. 5 representing the disposal of electronic components in a scattered manner.

Moreover, regarding the shapes of the cover 7 and the base 8, taking into consideration the height of the components and a request for reduction in the thickness of the ECU, a structure as shown in FIG. 4 is conceivable in which, for example, the board is sandwiched by the cover 7 and the base 8 without protruding the cove 7 or the board is sandwiched by them with the cover 7 protruded outward of The ECU 1.

Furthermore, as shown in FIG. 2 and FIG. 5, the heat-generating components 3 are disposed on the board 2 in a scattered manner in both peripheral and central portions of the board, whereby the board 2 can be held evenly.

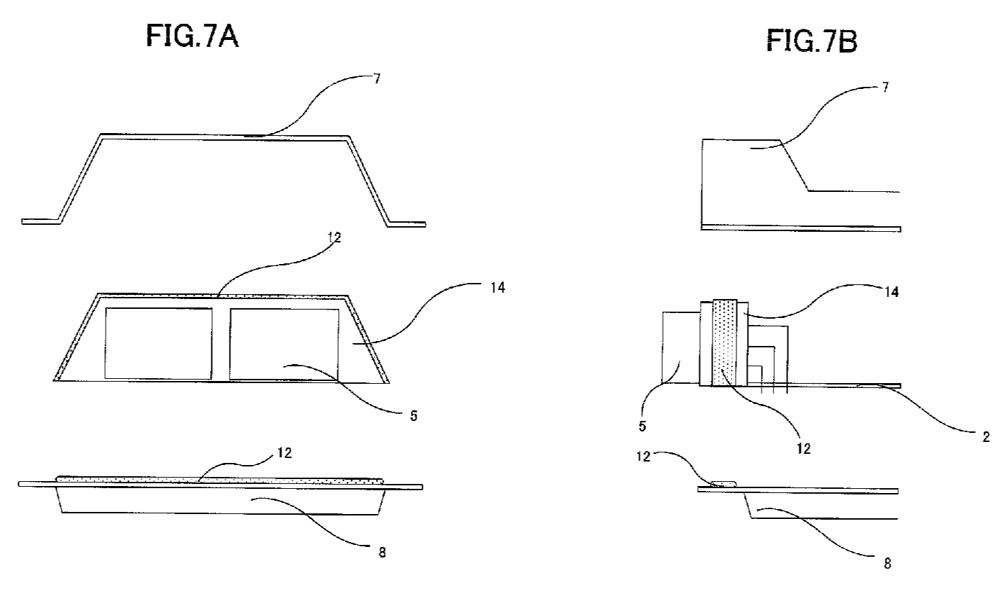

As shown in FIG. 2 and FIG. 3, the cover 7 and the base 8 are connected with the connector 5 using the glue 12 and the like. The connector 5 is provided with the connector holding member 14 that is integrated together with the connector or a separate piece, and the connector holding member 14 is structurally sandwiched at the perimeter thereof by the cover 7 and the base 8 via the glue 12 as shown in the plan view of FIG. 7A and the side view of FIG. 7B. Here, increase in the area of the connector holding member 14 contacting the cover 7 and the base 8 can enhance its holding strength.

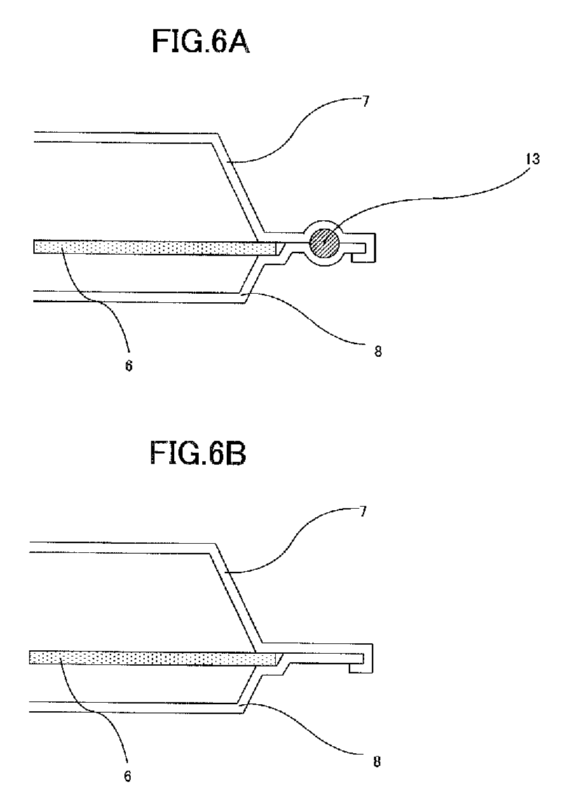

Moreover, in terms of the connection between the cover 7 and the base 8, there are conceivable methods: they are, for example, a method of connecting the cover and the base with each other, using a packing 13 instead of the glue, by caulking by bending the enclosure as shown in FIG. 6A, and furthermore, if waterproof is not necessary, a method of connecting them only by caulking as shown in FIG. 6B. Similarly, also in terms of connection of the connector holding member 14 with the cover 7 and the base 8, the connection can be made via not only the glue but also a packing, an intermediate member having flexibility, or the like. Furthermore, if waterproof is not necessary, the contact portions of the connector holding member 14, the cover 7 and the base 8, at which they contact each other, are embossed and/or recessed so as to perform their positioning, and they may be engaged with each other without interposing any intermediate member. Of course, there would be no problem even if those methods are mutually combined and implemented.

As described above, in an electric control unit according to Embodiment 1 of the present invention, the board can be sandwiched perpendicularly to the surfaces, at a plurality of points, by the enclosure and the thermal conductors, whereby the board can be held. Since screws and the like are not necessary for holding the board as in the conventional structure, the assembly process can be simplified, and the number of components and processes can be decreased, whereby effects of reducing manufacturing costs can be brought about. Moreover, heat from the heat-generating electronic components is dissipated from both of the mount surface and the opposite mount surface, whereby heat dissipation capability per unit board area can be enhanced, and as a result, reduction in the size and weight of the electronic control unit can be realized through the enhancement of the heat dissipation capability.

Various modifications and alterations of this invention will be apparent to those skilled in the art without departing from the scope and spirit of this invention, and it should be understood that this is not limited to the illustrative embodiments set forth herein.

What is claimed is:

1. An electronic control unit including an electronic circuit board mounted with a plurality of electronic components disposed in a scattered manner on one or both surfaces of the board and at least one connector, the electronic circuit board structurally being housed in an enclosure made up of enclosure members including a cover and a base, wherein
the electronic control unit is structured in such a way that intermediate members each are disposed on both top face of a part of or all of the electronic components and the electronic components' projected area on an opposite mount surface of the board, portions of the enclosure members are made to closely contact the intermediate members so that both surfaces of the electronic circuit board are sandwiched by the enclosure members and the intermediate members, and an edge portion in the periphery of the electronic circuit board is sandwiched by the enclosure members.

2. An electronic control unit according to claim 1, wherein the electronic control unit is structured in such a way that a connector holding member provided on the connector is sandwiched by the enclosure members so as to hold the electronic circuit board at multiple points.

3. An electronic control unit according to claim 2, wherein components, out of the electronic components, that are sandwiched by the enclosure members and the intermediate members are disposed at least two locations in the periphery of the board and at least one locations in the center thereof.

4. An electronic control unit according to claim 1, wherein the intermediate members have at least one of characteristics including flexibility, resilience and thermal conductivity.
